(19) United States
(12) Patent Application Publication
(10) Pub. No.: US 2021/0018833 A1
(43) Pub. Date: Jan. 21, 2021

(54) CURABLE COMPOSITION FOR IMPRINTING, RELEASE AGENT, CURED PRODUCT, PATTERN FORMING METHOD, AND LITHOGRAPHY METHOD

(71) Applicant: FUJIFILM Corporation, Tokyo (JP)

(72) Inventors: Yuichiro GOTO, Shizuoka (JP); Akihiro HAKAMATA, Shizuoka (JP); Naoya SHIMOJU, Shizuoka (JP)

(73) Assignee: FUJIFILM Corporation, Tokyo (JP)

(21) Appl. No.: 17/030,496

(22) Filed: Sep. 24, 2020

Related U.S. Application Data
(63) Continuation of application No. PCT/JP2019/012323, filed on Mar. 25, 2019.

(30) Foreign Application Priority Data
Mar. 27, 2018 (JP) 2018-060919

(51) Int. Cl. G03F 7/00; G03F 7/004; G03F 7/029; C08F 2/50; C08F 22/10

(52) U.S. Cl. CPC G03F 7/0002; G03F 7/0041; C08F 22/1006; C08F 2/50; G03F 7/029

(57) ABSTRACT

A curable composition for imprinting according to an embodiment of the present invention includes a monofunctional polymerizable compound having the following structure, a photopolymerization initiator, and a release agent represented by the following Formula (I) or Formula (II).

The monofunctional polymerizable compound has the following structure:
a linear or branched alkyl group, or an alicyclic ring, an aromatic ring, or an aromatic heterocycle that is substituted with a linear or branched alkyl group.
   The release agent is represented by the following Formula (I) or Formula (II).

A¹-(B¹)ₓ₁-(D¹)_{y1}-(E¹)_{z1}-F¹ Formula (I),

A²-(B²)ₓ₂-(D²)_{y2}-(E²)_{z2}-F² Formula (II),

A¹ and A² represent a linear aliphatic hydrocarbon group having 4 to 11 carbon atoms, D¹ and D² represent an alkylene oxide structure, F¹ represents a polar functional group, and F² represents a hydrogen atom, or a linear, branched, or cyclic aliphatic hydrocarbon group having 4 to 11 carbon atoms. Further, the present invention relates to a release agent, a cured product, a pattern forming method, and a lithography method that relate to the curable composition for imprinting.

### CROSS-REFERENCE TO RELATED APPLICATIONS

This application is a Continuation of PCT International Application No. PCT/JP2019/012323 filed on Mar. 25, 2019, which claims priority under 35 U.S.C § 119(a) to Japanese Patent Application No. 2018-060919 filed on Mar. 27, 2018. Each of the above application(s) is hereby expressly incorporated by reference, in its entirety, into the present application.

### BACKGROUND OF THE INVENTION

### 1. Field of the Invention

The present invention relates to a curable composition for imprinting, a release agent, a cured product, a pattern forming method, and a lithography method.

### 2. Description of the Related Art

An imprint method is a technique of transferring a fine pattern to a material by pressing a mold (in general, referred to as “mold” or “stamper”) on which a pattern is formed against the material. By using the imprint method, a fine pattern can be formed easily and accurately. Therefore, recently, the application of the imprint method to various fields has been expected. In particular, a nanoimprint technique of forming a fine pattern on a nano-order level has attracted attention.

As the imprint method, methods called a thermal imprint method and a photoimprint method have been proposed depending on a transfer method. In the thermal imprint method, a fine pattern is formed by pressing a mold against a thermoplastic resin heated to a glass transition temperature (hereinafter, also referred to as “Tg”) or higher, cooling the thermoplastic resin, and releasing the mold. In this method, various materials can be selected, but there are problems in that a high pressure is required during pressing and it is difficult to form a fine pattern due to thermal shrinkage or the like.

On the other hand, in the photoimprint method, a curable composition for imprinting is photocured in a state where a mold is pressed against the curable composition for imprinting, and then the mold is released. Alternatively, an aspect where a curable composition for imprinting is applied to a mold side and a substrate is pressed against the mold side may be adopted. Since this photoimprint method is an imprint method of irradiating an uncured product with light, a fine pattern can be simply formed without requiring high-pressure and high-temperature heating.

In the photoimprint method, a curable composition for imprinting is applied to a substrate (on which an adhesion treatment is optionally performed), and a mold formed of a light-transmitting material such as quartz is pressed against the curable composition for imprinting. In a case where the mold is pressed against the curable composition for imprinting, the curable composition for imprinting is cured by light irradiation, and then the mold is released. As a result, a cured product to which a desired pattern is transferred is prepared.

Examples of a method of applying the curable composition for imprinting to the substrate include a spin coating method and an ink jet method. In particular, the ink jet method is an application method that has recently attracted attention from the viewpoint of a small loss of the curable composition for imprinting.

In addition, a method of performing microfabrication using a transferred imprint pattern as a mask is called nanoimprint lithography (NIL), and has been developing as the next-generation lithography technique in place of the current ArF immersion process. Therefore, as in the case of an extreme ultraviolet (EUV) resist, a curable composition for imprinting used in NIL is required to have resolution ability of an ultrafine pattern having a size of 20 nm or less and high etching resistance as a mask during microfabrication of an object to be processed. Further, since throughput (productivity) is also emphasized during mass-production, nanoimprint suitability such as pattern filling properties (filling time reduction) and mold releasability (mold releasing time reduction) is also required.

As patent documents that disclose curable compositions for imprinting to which the above-described imprint method is applicable, JP2015-179807A, JP2016-029138A, JP2016-030829A, JP2013-189537A, JP2011-251508A, JP2015-130535A, JP2007-523249A, and JP2015-128134A are known. In JP2015-179807A, JP2016-029138A, and JP2016-030829A, phenyl ethylene glycol diacrylate is used as an acrylate monomer having high etching resistance. In addition, in JP2013-189537A, a polyfunctional acrylate having at least one of an alicyclic structure or an aromatic ring structure is used. Further, in JP2011-251508A and JP2015-130535A, an acrylate monomer including silicon is used in order to improve etching resistance. JP2007-523249A discloses an imprinting material that is formed of a composition including: a surfactant; a polymerizable component; and an initiator that responds to a stimulus to vary a viscosity in response to the stimulus, in which properties in a liquid state and properties in a solid state are regulated. JP2015-128134A adopts a curable composition that is prevented from being unevenly dispersed on a gas-liquid interface as an internal addition type release agent in consideration of a filling speed into a mold and releasability. Further, WO2016/152597A adopts a polymerizable compound having a hydrocarbon group in order to improve releasability.

### SUMMARY OF THE INVENTION

Regarding the imprint method, recently, techniques have been increasingly developed. Accordingly, requirements for properties have also become significantly strict, and properties corresponding to various needs have been required at a high level. One of the properties is, for example, releasability from a mold. In the imprint method, as described above, a curable composition for imprinting is applied to a substrate or a mold, the substrate and the mold are pressed against each other to imprint the curable composition for imprinting, and the curable composition is cured. Next, the mold is released from the cured product (also referred to as “cured film” or “imprinted layer”) of the curable composition for imprinting to obtain a cured product having a desired pattern. At this time, in a case where the adhesion force between the substrate and the cured product is not sufficiently high, a part or the entirety of the cured product is released together with the mold during the mold release. Accordingly, in order to accurately release the cured product from the mold in a state where the cured product is bonded to the substrate side, a release agent or a specific polymerizable compound is used.

On the other hand, it is required that a pattern exactly conforming to the mold is formed with the curable composition for imprinting. Therefore, filling properties into the mold are required. However, in general, in a case where the release agent or the specific polymerizable compound is mixed, filling properties into the mold tend to be poor.

The present invention has been made in order to solve the above-described problems, and an object thereof is to provide a curable composition for imprinting capable of achieving releasability and filling properties at the same time, a release agent, a cured product, a pattern forming method, and a lithography method.

The present inventors conducted an investigation under the above-described circumstances and found that the above-described problems can be solved by using a specific release agent for a curable composition for imprinting. Specifically, the above-described problems can be solved using the following configurations <1>, preferably <2> to <18>.

<1> A curable composition for imprinting comprising:
a monofunctional polymerizable compound;
a photopolymerization initiator; and
a release agent,
in which the monofunctional polymerizable compound has any one of the following structures (1) to (3):
(1) a linear alkyl group having 8 or more carbon atoms;
(2) a branched alkyl group having 10 or more carbon atoms; and
(3) an alicyclic ring, an aromatic ring, or an aromatic heterocycle that is substituted with a linear alkyl group having 1 or more carbon atoms or a branched alkyl group having 3 or more carbon atoms, and
the release agent is represented by the following Formula (I) or Formula (II),

A¹-(B¹)ₓ₁-(D¹)_{y1}-(E¹)_{z1}-F¹ Formula (I),
in Formula (I), A¹ represents a linear aliphatic hydrocarbon group having 4 to 11 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, A¹ does not have a fluorine atom, B¹ represents a divalent linking group in which a binding site to A¹ is not an aliphatic hydrocarbon group, x1 represents 0 or 1, D¹ represents an alkylene oxide structure, E¹ represents a divalent linking group in which a binding site to F¹ is not an aliphatic hydrocarbon group, F¹ represents a polar functional group, y1 represents an integer of 0 to 30, and z1 represents 0 or 1, and

A²-(B²)ₓ₂-(D²)_{y2}-(E²)_{z2}-F² Formula (II),
in Formula (II), A² represents a linear aliphatic hydrocarbon group having 4 to 11 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, A² does not have a fluorine atom, B² represents a divalent linking group in which a binding site to A² is not an aliphatic hydrocarbon group, x2 represents 0 or 1, D² represents an alkylene oxide structure, E² represents a divalent linking group in which a binding site to F² is not an aliphatic hydrocarbon group, F² represents a hydrogen atom, a linear aliphatic hydrocarbon group having 4 to 11 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, F² does not have a fluorine atom, y2 represents an integer of 0 to 30, z2 represents 0 or 1, and in a case where y2 represents 0, B² or E² represents a polar functional group.

<2> The curable composition for imprinting according to <1>, comprising:
a release agent in which A¹ represents a linear aliphatic hydrocarbon group having 4 to 9 carbon atoms.

<3> The curable composition for imprinting according to <1>, comprising:
a release agent in which A¹ represents a linear aliphatic hydrocarbon group having 4 to 9 carbon atoms and F² represents a linear aliphatic hydrocarbon group having 4 to 9 carbon atoms.

<4> The curable composition for imprinting according to any one of <1> to <3>,
in which the polar functional group is selected from the group consisting of a hydroxyl group, an amino group, a sulfonyl group-containing group, a sulfino group, a sulfonimidoyl group-containing group, and a carboxyl group.

<5> The curable composition for imprinting according to any one of <1> to <4>,
in which y1 and y2 each independently represent an integer of 5 to 20.

<6> The curable composition for imprinting according to any one of <1> to <5>,
in which x1 and x2 represent 0.

<7> The curable composition for imprinting according to any one of <1> to <6>,
in which in Formula (I), A¹ represents a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, and y1 represents an integer of 5 to 20, or
in Formula (II), A¹ represents a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, F² represents a hydrogen atom, a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, and y2 represents an integer of 5 to 20.

<8> The curable composition for imprinting according to any one of <1> to <7>,
in which a weight-average molecular weight of the release agent is 300 to 1000.

<9> The curable composition for imprinting according to any one of <1> to <8>,
in which a content of the release agent is 0.5 mass % to 7.0 mass % with respect to non-volatile components.

<10> The curable composition for imprinting according to any one of <1> to <9>,
in which the polymerizable compound included in the curable composition for imprinting exhibits a surface tension of 33 mN/m or higher at 23° C.

<11> The curable composition for imprinting according to any one of <1> to <10>,
in which a viscosity of the polymerizable compound included in the curable composition for imprinting is 20 mPa·s or lower, and
a solvent content in the composition is 3 mass % or lower with respect to the curable composition for imprinting.

<12> The curable composition for imprinting according to any one of <1> to ><11>,
in which a surface tension of the curable composition for imprinting at 23° C. is 28 mN/m to 38 mN/m.

<13> A release agent represented by the following Formula (I) or Formula (II),

A¹-(B¹)ₓ₁-(D¹)_{y1}-(E¹)_{z1}-F¹ Formula (I),
in Formula (I), A¹ represents a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, A¹ does not have a fluorine atom, B¹ represents a divalent linking group in which a binding site to A¹ is not an aliphatic hydrocarbon group, x1 represents 0 or 1, D¹ represents an alkylene oxide structure, E¹ represents a divalent linking group in which a binding site to F¹ is not an aliphatic hydrocarbon group, F¹ represents a polar functional group, y1 represents an integer of 5 to 20, and z1 represents 0 or 1, and

A²-(B²)ₓ₂-(D²)_{y2}-(E²)_{z2}-F² Formula (II),
in Formula (II), A² represents a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, A² does not have a fluorine atom, B² represents a divalent linking group in which a binding site to A² is not an aliphatic hydrocarbon group, x2 represents 0 or 1, D² represents an alkylene oxide structure, E² represents a divalent linking group in which a binding site to F² is not an aliphatic hydrocarbon group, F² represents a hydrogen atom, a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, F² does not have a fluorine atom, y2 represents an integer of 5 to 20, z2 represents 0 or 1, and in a case where y2 represents 0, B² or E² represents a polar functional group.

<14> The release agent according to <13>, which is used for a curable composition for imprinting.

<15> A cured product which is obtained by curing the curable composition for imprinting according to any one of <1> to <12>.

<16> The cured product according to <15>, which is provided on a silicon substrate.

<17> A pattern forming method comprising:
applying the curable composition for imprinting according to any one of <1> to <12> to a substrate or a mold; and irradiating the curable composition for imprinting with light in a state where the curable composition for imprinting is interposed between the mold and the substrate.

<18> The pattern forming method according to <17>,
in which a pattern to be formed has a shape of any one of a line, a ball, or a pillar having a size of 20 nm or less.

<19> A lithography method comprising:
performing etching by using a pattern which is obtained using the pattern forming method according to <17> or <18> as a mask.

According to an aspect of the present invention, it is possible to provide a curable composition for imprinting capable of achieving excellent releasability and excellent filling properties at the same time, a release agent, a cured product, a pattern forming method, and a lithography method.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, “(meth)acrylate” denotes acrylate and methacrylate, “(meth)acryl” denotes acryl and methacryl, and “(meth)acryloyl” denotes acryloyl and methacryloyl. “(meth)acryloyloxy” denotes acryloyloxy and methacryloyloxy.

In the present specification, “imprint” denotes preferably transfer of a pattern having a size of 1 nm to 10 mm and more preferably transfer of a pattern having a size of about 10 nm to 100 μm (nanoimprint).

In the present specification, unless specified as a substituted group or as an unsubstituted group, a group (atomic group) denotes not only a group having no substituent but also a group having a substituent. For example, “alkyl group” denotes not only an alkyl group having no substituent (unsubstituted alkyl group) but also an alkyl group having a substituent (substituted alkyl group).

In the present specification, “light” refers to not only light in, for example, ultraviolet, near-ultraviolet, far-ultraviolet, visible, and infrared wavelength ranges and an electromagnetic wave but also radiation. Examples of the radiation include a microwave, an electron beam, extreme ultraviolet (EUV) radiation, and an X-ray. In addition, laser light such as 248 nm excimer laser light, 193 nm excimer laser light, or 172 nm excimer laser light can also be used. As these light components, monochromatic light (single-wavelength light) having passed through an optical filter may also be used, or light (complex light) having a plurality of different wavelengths may also be used.

Unless specified otherwise, an atmospheric pressure during boiling point measurement in the present invention denotes 1013.25 hPa (1 atm).

In the present specification, the term “step” denotes not only an individual step but also a step which is not clearly distinguishable from another step as long as an effect expected from the step can be achieved.

A curable composition for imprinting according to an embodiment of the present invention comprises a specific polymerizable compound, a photopolymerization initiator, and a release agent represented by the following Formula (I) or Formula (II). Hereinafter, the details of the present invention will be described.

<Curable Composition for Imprinting>

<<Polymerizable Compounds>>

<<Monofunctional Polymerizable Compound>>

The curable composition for imprinting according to the embodiment of the present invention includes a monofunctional polymerizable compound having any one of the following structures (1) to (3) (hereinafter, also referred to as “specific monofunctional polymerizable compound”).

(1) a linear alkyl group having 8 or more carbon atoms

(2) a branched alkyl group having 10 or more carbon atoms

(3) an alicyclic ring, an aromatic ring, or an aromatic heterocycle that is substituted with a linear alkyl group having 1 or more carbon atoms or a branched alkyl group having 3 or more carbon atoms (that is, an alicyclic ring that is substituted with a linear alkyl group having 1 or more carbon atoms or a branched alkyl group having 3 or more carbon atoms, an aromatic ring that is substituted with a linear alkyl group having 1 or more carbon atoms or a branched alkyl group having 3 or more carbon atoms, or an aromatic heterocycle that is substituted with a linear alkyl group having 1 or more carbon atoms or a branched alkyl group having 3 or more carbon atoms)

(1) Linear Alkyl Group having 8 or more Carbon Atoms

The linear alkyl group having 8 or more carbon atoms has more preferably 10 or more carbon atoms, still more preferably 11 or more carbon atoms, and still more preferably 12 or more carbon atoms. The linear alkyl group having 8 or more carbon atoms has preferably 20 or less carbon atoms, more preferably 18 or less carbon atoms, still more preferably 16 or less carbon atoms, and still more preferably 14 or less carbon atoms.

(2) a branched alkyl group having 10 or more carbon atoms

The branched alkyl group having 10 or more carbon atoms has preferably 10 to 20 carbon atoms, more preferably 10 to 16 carbon atoms, still more preferably 10 to 14 carbon atoms, and still more preferably 10 to 12 carbon atoms.

(3) alicyclic ring that is substituted with linear alkyl group having 1 or more carbon atoms or branched alkyl group having 3 or more carbon atoms, aromatic ring that is substituted with linear alkyl group having 1 or more carbon atoms or branched alkyl croup having 3 or more carbon atoms, or aromatic heterocycle that is substituted with linear alkyl group having 1 or more carbon atoms or branched alkyl group having 3 or more carbon atoms

The linear alkyl group having 1 or more carbon atoms or the branched alkyl group having 3 or more carbon atoms is more preferably a linear alkyl group having 1 or more carbon atoms. The number of carbon atoms in the linear alkyl group having 1 or more carbon atoms is preferably 4 or more and more preferably 6 or more. The number of carbon atoms in the branched alkyl group is preferably 4 or more, more preferably 6 or more, and still more preferably 8 or more. The number of carbon atoms in the linear alkyl group having 1 or more carbon atoms is preferably 14 or less, more preferably 12 or less, and still more preferably 10 or less.

The ring in the alicyclic ring, the aromatic ring, or the aromatic heterocycle may be a monocycle or a fused ring and is preferably a monocycle. In a case where the ring is a fused ring, the number of rings is preferably 2 or 3. As the ring, a 3- to 8-membered ring is preferable, a 5- or 6-membered ring is more preferable, and a 6-membered ring is still more preferable. Specific examples of the ring include examples of a ring Cz described below.

It is preferable that the structure of (3) is a structure represented by the following Formula (A1).

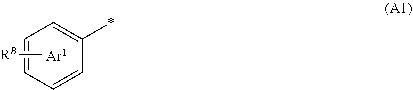

In the formula, Ar¹ represents an aromatic ring, in which the number of carbon atoms is preferably 6 to 22, more preferably 6 to 18, and still more preferably 6 to 10. Specifically, a benzene ring or a naphthalene ring is preferable. Ar¹ may have a substituent T within a range where the effects of the present invention can be exhibited. R^{B} represents the linear alkyl group or the branched alkyl group defined in (3), and a preferable range thereof is also the same. * represents a binding site.

The molecular weight of the specific monofunctional polymerizable compound is preferably 50 or higher, more preferably 100 or higher, and still more preferably 150 or higher. The molecular weight is preferably 1000 or lower, more preferably 800 or lower, still more preferably 300 or lower, and still more preferably 270 or lower. There is a tendency that, by adjusting the molecular weight to be the above-described lower limit value or lower, volatility can be suppressed. There is a tendency that, by adjusting the molecular weight to be the above-described upper limit value or lower, viscosity can be reduced.

The boiling point of the specific monofunctional polymerizable compound is preferably 85° C. or higher, more preferably 110° C. or higher, and still more preferably 130° C. or higher. By adjusting the boiling point to be the above-described lower limit value or higher, volatility can be suppressed. The upper limit value of the boiling point is not particularly limited. For example, the boiling point may be 350° C. or lower.

It is preferable that at least a part of the specific monofunctional polymerizable compound is liquid at 23° C., and it is more preferable that 15 mass % or higher of the polymerizable compound included in the curable composition for imprinting is liquid at 23° C.

The kind of a polymerizable group included in the specific monofunctional polymerizable compound is not particularly limited, and examples of the polymerizable group include an ethylenically unsaturated group and an epoxy group. Among these, an ethylenically unsaturated group is preferable. The ethylenically unsaturated group is preferably a (meth)acryloyl group and more preferably an acryloyl group.

The kind of atoms forming the specific monofunctional polymerizable compound is not particularly limited, it is preferable that the specific monofunctional polymerizable compound consists of only atoms selected from the group consisting of a carbon atom, an oxygen atom, a hydrogen atom, and a halogen atom, and it is more preferable that the specific monofunctional polymerizable compound consists of only atoms selected from the group consisting of a carbon atom, an oxygen atom, and a hydrogen atom.

As the specific monofunctional polymerizable compound, a compound in which a linear or branched hydrocarbon chain having 4 or more carbon atoms and a polymerizable group are bonded to each other directly or through a linking group is preferable, and a compound in which one group selected from the groups (1) to (3) and a polymerizable group are bonded to each other directly is more preferable. Examples of the linking group include —O—, —C(═O)—, —CH₂—, and a combination thereof. As the monofunctional polymerizable compound used in the present invention, (1) a linear alkyl (meth)acrylate in which the linear alkyl group having 8 or more carbon atoms and a (meth)acryloyloxy group are directly bonded to each other is more preferable.

It is preferable that the specific monofunctional polymerizable compound is a compound represented by the following Formula (I-1).

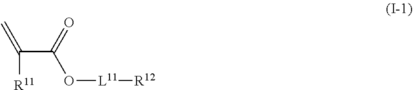

R¹² represents a structure represented by any one of (1) to (3). R¹¹ represents a hydrogen atom or a methyl group. L¹¹ represents a single bond or a linking group L described below and preferably a single bond, an alkylene group (having preferably 1 to 12 carbon atoms, more preferably 1 to 6 carbon atoms, and still more preferably 1 to 3 carbon atoms), or an alkenylene group (having preferably 2 to 24 carbon atoms, more preferably 2 to 12 carbon atoms, and still more preferably 2 to 6 carbon atoms). R¹² and L¹¹ may be bonded through or without the linking group L to form a ring. R¹² and L¹¹ may further have the above-described substituent T. A plurality of the substituents T may be bonded to form a ring, and the substituent T and R¹² or L¹¹ may be bonded to form a ring. In a case where a plurality of substituents T are present, the substituents T may be the same as or different from each other. A preferable range of the alicyclic ring, the aromatic ring, or the aromatic heterocycle in the structure of (3) of R¹² include, for example, the following rings aCy, hCy, and fCy, which will be collectively referred to as “ring Cz”. In a case where R¹² represents the structure of (3), it is preferable that R¹² represents a group represented by Formula (A1).

The number of carbon atoms in the alicyclic ring fCy is preferably 3 to 22, more preferably 4 to 18, and still more preferably 6 to 10. Specific examples of the alicyclic ring fcy include a cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a tetrahydrodicyclopentadiene ring, an octahydronaphthalene ring, a decahydronaphthalene ring, a hexahydroindane ring, a bornane ring, a norbornane ring, a norbornene ring, a isobornane ring, a tricyclodecane ring, a tetracyclododecane ring, and an adamantane ring.

The number of carbon atoms in the aromatic ring aCy is preferably 6 to 22, more preferably 6 to 18, and still more preferably 6 to 10. Specific examples of the aromatic ring include a benzene ring, a naphthalene ring, an anthracene ring, a phenanthrene ring, a phenalene ring, a fluorene ring, an acenaphthylene ring, a biphenylene ring, an indene ring, an indane ring, a triphenylene ring, a pyrene ring, a chrysene ring, a perylene ring, and a tetrahydronaphthalene ring. Among these, a benzene ring or a naphthalene ring is preferable, and a benzene ring is more preferable. The aromatic ring may have a structure in which a plurality of rings are linked to each other, and examples thereof include a biphenyl ring and a bisphenyl ring.

The number of carbon atoms in the aromatic heterocycle hCy is preferably 1 to 12, more preferably 1 to 6, and still more preferably 1 to 5. Specific examples of the aromatic heterocycle include a thiophene ring, a furan ring, a pyrrole ring, an imidazole ring, a pyrazole ring, a triazole ring, a tetrazole ring, a thiazole ring, an oxazole ring, a pyridine ring, a pyrazine ring, a pyrimidine ring, a pyridazine ring, an isoindole ring, an indole ring, an indazole ring, a purine ring, a quinolizine ring, an isoquinoline ring, a quinoline ring, a phthalazine ring, a naphthyridine ring, a quinoxaline ring, a quinazoline ring, a cinnoline ring, a carbazole ring, an acridine ring, a phenazine ring, a phenothiazine ring, and a phenoxazine ring.

As the specific monofunctional polymerizable compound, compounds used in Examples described below can be used, but the present invention is not limited to this configuration.

It is presumed that, in the curable composition for imprinting according to the embodiment of the present invention, by using the above-described specific monofunctional polymerizable compound (a polymerizable compound such as (1) or (2) that has a saturated aliphatic substituent having a relatively large number of carbon atoms or a polymerizable compound such as (3) that includes an aromatic ring or an aromatic heterocycle having a saturated aliphatic substituent) and a release agent including a site defined by A¹ or A′, excessive segregation of the specific polymerizable compound on a gas-liquid interface is suppressed, and filling properties are improved. However, the above-described action includes assumptions, and the present invention is not limited to this configuration.

The content of the specific monofunctional polymerizable compound used in the curable composition for imprinting is preferably 6 mass % or higher, more preferably 8 mass % or higher, still more preferably 10 mass % or higher, and still more preferably 12 mass % or higher with respect to all the polymerizable compounds. In addition, the content is more preferably 60 mass % or lower and may be 55 mass % or lower. In particular, in the present invention, it is preferable that the following polyfunctional polymerizable compound is used and is a major component.

In the present invention, as the specific monofunctional polymerizable compound, only one kind may be included, or two or more kinds may be included. In a case where the curable composition for imprinting according to the embodiment of the present invention includes two or more specific monofunctional polymerizable compounds, it is preferable that the total content of the two or more specific monofunctional polymerizable compounds is in the above-described range. The curable composition for imprinting may include not only the specific monofunctional polymerizable compound but also other monofunctional polymerizable compounds.

<<<Polyfunctional Polymerizable Compound>>>

As described above, it is preferable that the curable composition for imprinting includes not only the specific monofunctional polymerizable compound but also a polyfunctional polymerizable compound. The polyfunctional polymerizable compound is not particularly limited and is preferably a compound including at least one of an alicyclic ring, an aromatic ring, or an aromatic heterocycle and more preferably a compound including at least one of an aromatic ring or an aromatic heterocycle. In the following description, the compound including at least one an alicyclic ring, an aromatic ring, or an aromatic heterocycle will also be referred to as “ring-containing polyfunctional polymerizable compound”.

The molecular weight of the ring-containing polyfunctional polymerizable compound used in the curable composition for imprinting is preferably 1000 or lower, more preferably 800 or lower, still more preferably 500 or lower, and still more preferably 350 or lower. There is a tendency that, by adjusting the upper limit value of the molecular weight to be 1000 or lower, the viscosity can be reduced. The lower limit value of the molecular weight is not particularly limited and is, for example, 200 or higher.

The number of polymerizable groups in the ring-containing polyfunctional polymerizable compound used in the curable composition for imprinting is 2 or more, preferably 2 to 7, more preferably 2 to 4, still more preferably 2 or 3, and still more preferably 2.

The kind of the polymerizable group included in the ring-containing polyfunctional polymerizable compound used in the curable composition for imprinting is not particularly limited, and examples of the polymerizable group include an ethylenically unsaturated group and an epoxy group. Among these, an ethylenically unsaturated group is preferable. The ethylenically unsaturated group is preferably a (meth)acryloyl group and more preferably an acryloyl group. Two or more kinds of polymerizable groups may be included in one molecule, or the same kind of two or more polymerizable groups may be included in one molecule.

The kind of atoms forming the ring-containing polyfunctional polymerizable compound used in the curable composition for imprinting is not particularly limited, it is preferable that the ring-containing polyfunctional polymerizable compound consists of only atoms selected from the group consisting of a carbon atom, an oxygen atom, a hydrogen atom, and a halogen atom, and it is more preferable that the ring-containing polyfunctional polymerizable compound consists of only atoms selected from the group consisting of a carbon atom, an oxygen atom, and a hydrogen atom.

The ring included in the ring-containing polyfunctional polymerizable compound used in the curable composition for imprinting may be a monocycle or a fused ring and is preferably a monocycle. In a case where the ring is a fused ring, the number of rings is preferably 2 or 3. As the ring, a 3- to 8-membered ring is preferable, a 5- or 6-membered ring is more preferable, and a 6-membered ring is still more preferable. In addition, the ring may be an alicyclic ring, an aromatic ring, or an aromatic heterocycle and is preferably an aromatic ring or an aromatic heterocycle and more preferably an aromatic ring. Specific examples of the ring include the examples of the ring Cz.

The number of rings in the ring-containing polyfunctional polymerizable compound used in the curable composition for imprinting may be one or two or more and is preferably one or two and more preferably one. In the case of the fused ring, the fused ring is considered as one ring.

It is preferable that a structure of the ring-containing polyfunctional polymerizable compound used in the curable composition for imprinting is represented by (polymerizable group)-(single bond or divalent linking group)-(divalent group having ring)-(single bond or divalent linking group)-(polymerizable group). Here, the linking group is more preferably an alkylene group and still more preferably an alkylene group having 1 to 3 carbon atoms.

It is preferable that the ring-containing polyfunctional polymerizable compound used in the curable composition for imprinting is represented by the following Formula (I-2).

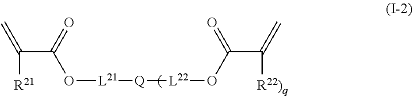

Q represents a (1+q)-valent group including at least one selected from an alicyclic ring (having preferably 3 to 24 carbon atoms, more preferably 3 to 12 carbon atoms, and still more preferably 3 to 6 carbon atoms), an aromatic ring (having preferably 6 to 22 carbon atoms, more preferably 6 to 18 carbon atoms, and still more preferably 6 to 10 carbon atoms), or an aromatic heterocycle (having preferably 1 to 12 carbon atoms, more preferably 1 to 6 carbon atoms, and still more preferably 1 to 5 carbon atoms). R^{2′} and R²² each independently represent a hydrogen atom or a methyl group. L²¹ and L²² each independently represent a single bond or a linking group L described below. Q and L²¹ or L²² may be bonded through or without the linking group L to form a ring. Q, L²¹, and L²² may have the above-described substituent T. A plurality of the substituents T may be bonded to form a ring, and the substituent T and Q, L²¹, or L²² may be bonded to form a ring. In a case where a plurality of substituents T are present, the substituents T may be the same as or different from each other. Preferable ranges of the alicyclic ring, the aromatic ring, or the aromatic heterocycle in Q are the same as those in the ring Cz. q represents an integer of 1 to 5, preferably an integer of 1 to 3, more preferably 1 or 2, and still more preferably 1.

Q may have a structure in which a plurality of alicyclic rings, a plurality of aromatic rings, a plurality of aromatic heterocycles, an alicyclic ring and an aromatic ring, an alicyclic ring and an aromatic heterocycle, or an aromatic ring and an aromatic heterocycle are linked. Examples of the structure in which the aromatic ring is linked include a structure represented by the following Formula AR-1 or AR-2.

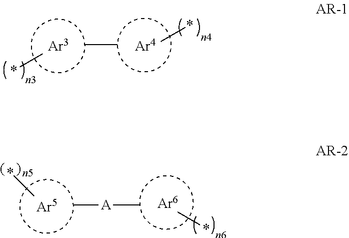

In the formula, Ar³ to Ar⁶ each independently represent an aromatic ring, an aromatic heterocycle, or an alicyclic ring, and preferable examples thereof include the ring Cz. A represents a linking group, and examples thereof include examples of the linking group L. It is preferable that A represents a divalent group selected from the group consisting of —CH₂—, —O—, —S—, —SO₂—, and —C(CH₃)₂— which may be substituted with a halogen atom (in particular, a fluorine atom). Ar³ to Ar⁶ may have the substituent T. In a case where a plurality of substituents T are present, the substituents T may be bonded to each other or may be bonded to the ring Ar³ to Ar⁶ in the formula through or without the linking group L to form a ring. In addition, the substituent T may be bonded to the linking group A or to the linking group L²¹ or L²² through or without the linking group L to form a ring. * represents a binding site to L²¹ or L²². n3 to n6 each independently represent an integer of 1 to 3, preferably 2 or 3, and more preferably 1. However, n3+n4 and n5+n6 each independently represent 1+q.

Examples of the polyfunctional polymerizable compound used in the curable composition for imprinting include a first group and a second group. However, it is needless to say that the present invention is not limited to these examples. The first group is more preferable.

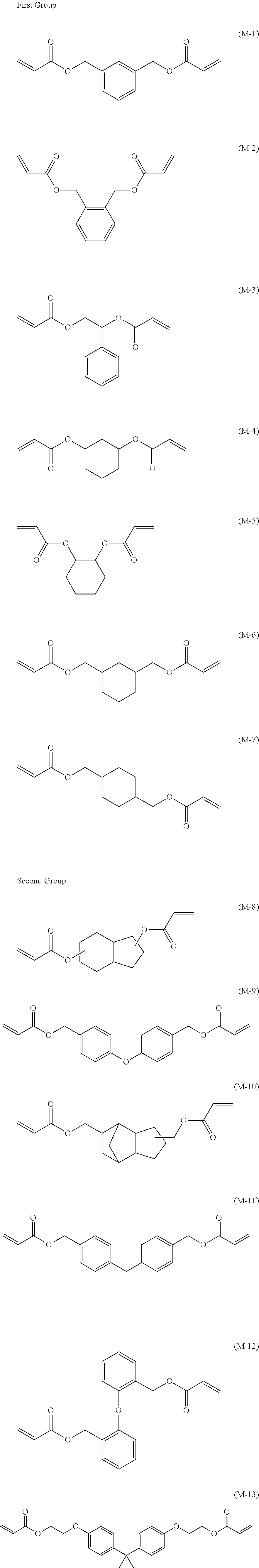

The curable composition for imprinting may include a polyfunctional polymerizable compound other than the above-described ring-containing polyfunctional polymerizable compound. As the other polyfunctional polymerizable compound, a compound represented by the following Formula (I-3) is preferable.

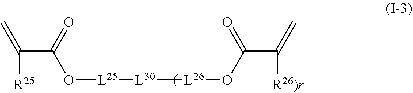

L30 represents a (1+r)-valent group including at least one selected from a group having a linear or branched alkane structure (having preferably 1 to 12 carbon atoms and more preferably 1 to 6 carbon atoms), a group having a linear or branched alkene structure (having preferably 2 to 12 carbon atoms and more preferably 2 to 6 carbon atoms), or a group having a linear or branched alkyne structure (having preferably 2 to 12 carbon atoms and more preferably 2 to 6 carbon atoms). R²⁵ and R²⁶ each independently represent a hydrogen atom or a methyl group. L²⁵ and L²⁶ each independently represent a single bond or a linking group L described below. L″ and L²⁵ or L²⁶ may be bonded through or without the linking group L to form a ring. L²⁵, L²⁶, and L″ may have the above-described substituent T. A plurality of the substituents T may be bonded to form a ring, and the substituent T and another linking group may be bonded to form a ring. In a case where a plurality of substituents T are present, the substituents T may be the same as or different from each other. r represents an integer of 1 to 5, preferably an integer of 1 to 3, more preferably 1 or 2, and still more preferably 1. In L³⁰, a linking group (O, S, NR^{N}) having a heteroatom may be interposed. It is preferable that the number of linking groups having a heteroatom interposed is one in 1 to 6 carbon atoms of L³⁰.

Examples of the other polyfunctional polymerizable compound used in the curable composition for imprinting include a polyfunctional polymerizable compound not having a ring among polymerizable compounds described in JP2014-170949A, the contents of which are incorporated herein by reference. More specifically, for example, the following compounds can be used.

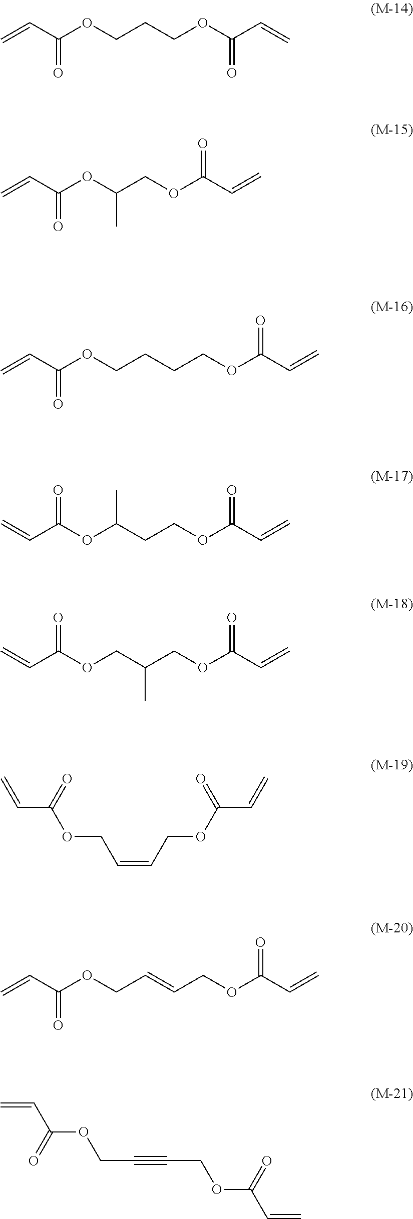

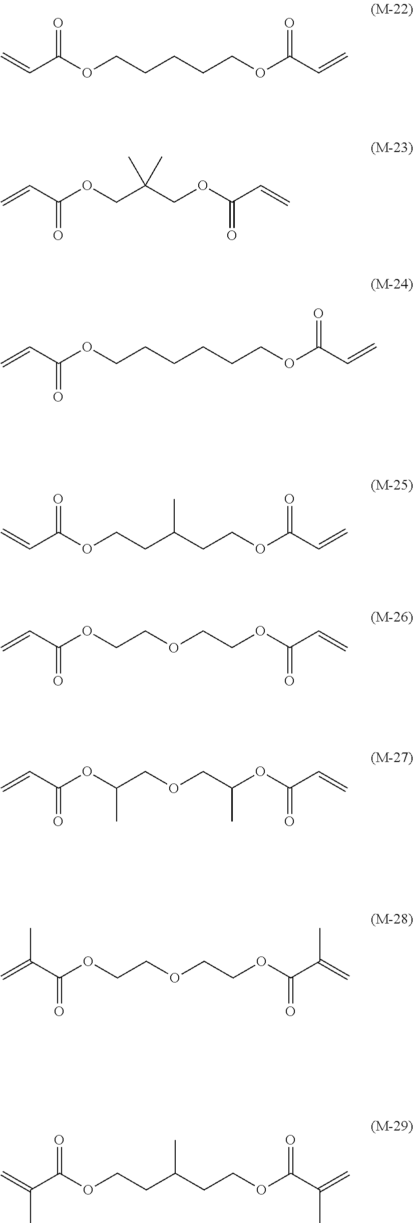

The content of the polyfunctional polymerizable compound is preferably 30 mass % or higher, and more preferably 45 mass % or higher and may be 50 mass % or higher or 55 mass % or higher with respect to all the polymerizable compounds in the curable composition for imprinting. In addition, the upper limit value is preferably lower than 95 mass % and more preferably 90 mass % or lower and may be 85 mass % or lower and 70 mass % or lower. Among the polyfunctional polymerizable compounds, a mass ratio (ring-containing polyfunctional polymerizable compound:other polyfunctional polymerizable compounds) of the ring-containing polyfunctional polymerizable compound to the other polyfunctional polymerizable compounds is preferably 30 to 90:10 to 70, more preferably 50 to 85:15 to 50, and still more preferably 60 to 80:20 to 40.

The curable composition for imprinting may include only one polyfunctional polymerizable compound or may include two or more polyfunctional polymerizable compounds. In a case where the curable composition for imprinting according to the embodiment of the present invention includes two or more polyfunctional polymerizable compounds, it is preferable that the total content of the two or more polyfunctional polymerizable compounds is in the above-described range.

In the curable composition for imprinting used in the present invention, the content of the polymerizable compound is preferably 85 mass % or higher, more preferably 90 mass % or higher, and still more preferably 93 mass % or higher with respect to the curable composition.

The substituent T include an alkyl group (having preferably 1 to 24 carbon atoms, more preferably 1 to 12 carbon atoms, and still more preferably 1 to 6 carbon atoms), a cycloalkyl group (having preferably 3 to 24 carbon atoms, more preferably 3 to 12 carbon atoms, and still more preferably 3 to 6 carbon atoms), an arylalkyl group (having preferably 7 to 21 carbon atoms, more preferably 7 to 15 carbon atoms, and still more preferably 7 to 11 carbon atoms), an alkenyl group (having preferably 2 to 24 carbon atoms, more preferably 2 to 12 carbon atoms, and still more preferably 2 to 6 carbon atoms), a cycloalkenyl group (having preferably 3 to 24 carbon atoms, more preferably 3 to 12 carbon atoms, and still more preferably 3 to 6 carbon atoms), a hydroxyl group, an amino group (having preferably 0 to 24 carbon atoms, more preferably 0 to 12 carbon atoms, and still more preferably 0 to 6 carbon atoms), a thiol group, a carboxyl group, an aryl group (having preferably 6 to 22 carbon atoms, more preferably 6 to 18 carbon atoms, and still more preferably 6 to 10 carbon atoms), an acyl group (having preferably 2 to 12 carbon atoms, more preferably 2 to 6 carbon atoms, and still more preferably 2 or 3 carbon atoms), an acyloxy group (having preferably 2 to 12 carbon atoms, more preferably 2 to 6 carbon atoms, and still more preferably 2 or 3 carbon atoms), an aryloyl group (having preferably 7 to 23 carbon atoms, more preferably 7 to 19 carbon atoms, and still more preferably 7 to 11 carbon atoms), an aryloyloxy group (having preferably 7 to 23 carbon atoms, more preferably 7 to 19 carbon atoms, and still more preferably 7 to 11 carbon atoms), a carbamoyl group (having preferably 1 to 12 carbon atoms, more preferably 1 to 6 carbon atoms, and still more preferably 1 to 3 carbon atoms), a sulfamoyl group (having preferably 0 to 12 carbon atoms, more preferably 0 to 6 carbon atoms, and still more preferably 0 to 3 carbon atoms), a sulfo group, an alkylsulfonyl group (having preferably 1 to 12 carbon atoms, more preferably 1 to 6 carbon atoms, and still more preferably 1 to 3 carbon atoms), an arylsulfonyl group (having preferably 6 to 22 carbon atoms, more preferably 6 to 18 carbon atoms, and still more preferably 6 to 10 carbon atoms), a heterocyclic group (having preferably 1 to 12 carbon atoms, more preferably 1 to 8 carbon atoms, and still more preferably 2 to 5 carbon atoms; having preferably a 5- or 6-membered ring), a (meth)acryloyl group, a (meth)acryloyloxy group, a halogen atom (for example, a fluorine atom, a chlorine atom, a bromine atom, or an iodine atom), an oxo group (═O), an imino group (═NR^{N}), and an alkylidene group (═C(R^{N})₂). R^{N} represents a hydrogen atom or an alkyl group (preferably an alkyl group having 1 to 12 carbon atoms, more preferably an alkyl group having 1 to 6 carbon atoms, still more preferably an alkyl group having 1 to 3 carbon atoms, and still more preferably a methyl group). The alkyl portion and the alkenyl portion included in each of the substituents may be linear or branched or may be chain-like or cyclic. In a case where the substituent T is a group which may have a substituent, the group may further have the substituent T. For example, the alkyl group may be an alkyl halide group, a (meth)acryloyloxyalkyl group, an aminoalkyl group, or a carboxyalkyl group. In a case where the substituent is a group that may form a salt such as a carboxyl group or an amino group, the group may form a salt.

Examples of the linking group L include a linear or branched alkylene group (having preferably 1 to 24 carbon atoms, more preferably 1 to 12 carbon atoms, and still more preferably 1 to 6 carbon atoms), an arylene group (having preferably 6 to 22 carbon atoms, more preferably 6 to 18 carbon atoms, and still more preferably 6 to 10 carbon atoms), —O—, —S—, —SO₂—, —CO—, —NR^{N}—, and a linking group relating to a combination thereof. The alkylene group may have the above-described substituent T. For example, the alkylene group may be a fluorinated alkylene group having a fluorine atom. The number of atoms included in the linking group L is preferably 1 to 24, more preferably 1 to 12, and still more preferably 1 to 6.

<<Release Agent>>

The curable composition for imprinting according to the embodiment of the present invention includes a release agent represented by the following Formula (I) or Formula (II).

A¹-(B¹)ₓ₁-(D¹)_{y1}-(E¹)_{z1}-F¹ Formula (I),

In Formula (I), A¹ represents a linear aliphatic hydrocarbon group having 4 to 11 carbon atoms (preferably 4 to 9 carbon atoms), a branched aliphatic hydrocarbon group having 5 to 18 carbon atoms (preferably 6 to 16 carbon atoms), or an aliphatic hydrocarbon group having 5 to 11 carbon atoms (including the number of carbon atoms in the cyclic structure) that has a cyclic structure having 5 or 6 carbon atoms, A¹ does not have a fluorine atom, B¹ represents a divalent linking group in which a binding site to A¹ is not an aliphatic hydrocarbon group, x1 represents 0 or 1, D¹ represents an alkylene oxide structure, E¹ represents a divalent linking group in which a binding site to F¹ is not an aliphatic hydrocarbon group, F¹ represents a polar functional group, y1 represents an integer of 0 to 30, and z1 represents 0 or 1.

A²-(B²)ₓ₂-(D²)_{y2}-(E²)_{z2}-F² Formula (II),

In Formula (II), A² represents a linear aliphatic hydrocarbon group having 4 to 11 carbon atoms (preferably 4 to 9 carbon atoms), a branched aliphatic hydrocarbon group having 5 to 18 carbon atoms (preferably 6 to 16 carbon atoms), or an aliphatic hydrocarbon group having 5 to 11 carbon atoms (including the number of carbon atoms in the cyclic structure) that has a cyclic structure having 5 or 6 carbon atoms, A² does not have a fluorine atom, B² represents a divalent linking group in which a binding site to A² is not an aliphatic hydrocarbon group, x2 represents 0 or 1, D² represents an alkylene oxide structure, E² represents a divalent linking group in which a binding site to F² is not an aliphatic hydrocarbon group, F² represents a hydrogen atom, a linear aliphatic hydrocarbon group having 4 to 11 carbon atoms (preferably 4 to 9 carbon atoms), a branched aliphatic hydrocarbon group having 5 to 18 carbon atoms (preferably 6 to 16 carbon atoms), or an aliphatic hydrocarbon group having 5 to 11 carbon atoms (not including the number of carbon atoms in the cyclic structure) that has a cyclic structure having 5 or 6 carbon atoms, F² does not have a fluorine atom, y2 represents an integer of 0 to 30, z2 represents 0 or 1, and in a case where y2 represents 0, B² or E² represents a polar functional group.

Regarding Hydrocarbon Group (A¹, A²)

The release agent includes the specific hydrocarbon groups A¹ and A², and thus is appropriately present on the gas-liquid interface. Therefore, excessive segregation of the hydrophobic polymerizable compound having the hydrocarbon chain on the interface can be prevented, and deterioration in filling properties caused by segregation of a hydrophobic component is suppressed. In a case where the polymerizable compound includes a linear alkyl group having 8 or more carbon atoms that has high segregation performance on the gas-liquid interface, the polymerizable compound functions more effectively.

The number of carbon atoms in the linear aliphatic hydrocarbon group of A¹ and A² is 4 to 11, preferably 5 or more, and more preferably 6 or more. In addition, the number of carbon atoms is preferably 9 or less.

The number of carbon atoms in the branched aliphatic hydrocarbon group is 5 to 18, preferably 6 or more, more preferably 7 or more, and still more preferably 8 or more and may be 9 or more. In addition, the number of carbon atoms is preferably 17 or less and may be 16 or less.

The aliphatic hydrocarbon group having 5 to 11 carbon atoms that has a cyclic structure having 5 or 6 carbon atoms may consist of only a cyclic structure or may consist of a cyclic structure and a linear or branched aliphatic hydrocarbon group. The cyclic structure is a 5- or 6-membered alicyclic ring. In addition, the cyclic structure may be a monocycle or a fused ring. It is preferable that the aliphatic hydrocarbon group having 5 to 11 carbon atoms that includes a cyclic structure having 5 or 6 carbon atoms in A¹ and A² is a group represented by the following Formula (A2).

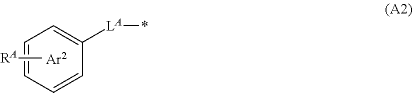

In the formula, Ar² represents an aromatic ring, in which the number of carbon atoms is preferably 6 to 22, more preferably 6 to 18, and still more preferably 6 to 10. Specifically, a benzene ring or a naphthalene ring is preferable. Ar² may have a substituent within a range where the effects of the present invention can be exhibited. R^{A} represents preferably a linear aliphatic hydrocarbon group having 4 to 11 carbon atoms (preferably 4 to 9 carbon atoms) or a branched aliphatic hydrocarbon group having 5 to 18 carbon atoms (preferably 6 to 16 carbon atoms). L^{A} represents a single bond or an alkylene group (preferably having 1 to 12 carbon atoms, more preferably 1 to 6 carbon atoms, and still more preferably 1 to 3 carbon atoms). * represents a binding site.

A¹ and A² represent a saturated hydrocarbon group and preferably do not have a substituent.

In a case where the number of carbon atoms in A¹ and A² is less than the lower limit value, hydrophobicity is weak. Therefore, the surface energy of a mold cannot be sufficiently reduced, and releasability deteriorates. Conversely, in a case where the number of carbon atoms in A¹ and A² is more than the upper limit value, hydrophobicity is excessively strong, the wettability on a mold surface deteriorates, and filling properties deteriorate. The reason why the range of the number of carbon atoms in the linear aliphatic hydrocarbon group is different from that in the branched aliphatic hydrocarbon group is that, since the ability to reduce the surface energy in the branched aliphatic hydrocarbon group is lower than that in the linear aliphatic hydrocarbon group, a large number of carbon atoms is required for the branched aliphatic hydrocarbon group. The action relating to the release agent in the present specification includes assumptions, and thus the present invention is not limited thereto.

A¹ and A² do not have a fluorine atom. In a case where A¹ and A² do not have a fluorine atom, an excessive decrease in surface energy of a mold surface can be prevented, and releasability can be improved without a decrease in filling properties. Further, it is preferable that A¹ and A² only consist of a carbon atom and a hydrogen atom. In a case where A¹ and A² only consist of a carbon atom and a hydrogen atom, the surface energy can be appropriately reduced.

Regarding Linking Group (B¹, B², E¹, E²)

The release agent may include or may not include a linking group. Accordingly, in the formula, x1, x2, z1, and z2 represent 0 or 1, and it is preferable that x1, x2, z1, and z2 represent 0.

B¹, B², E¹, and E² represent divalent linking groups in which linking sites to A¹, F¹, A², and F² are not aliphatic hydrocarbon groups, respectively.

A linking group according to a first embodiment is, for example, a linking group having a ring structure other than an aliphatic hydrocarbon. Examples of the ring structure forming the linking group include an aromatic ring. An aromatic ring having 6 to 18 carbon atoms (preferably 6 to 10 carbon atoms) such as a benzene ring or a naphthalene ring, or a heterocycle such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring is preferable.

A linking group according to a second embodiment is, for example, a group including a polar functional group.

In particular, in a case where y2 in Formula (II) represents 0, it is preferable that B² or E² includes a polar functional group. That is, at least one of x2 or z2 represents 1. In a case where B² or E² represents a linking group including a polar functional group, and an oxygen atom, a sulfur atom, a carbonyl group, —NR^{N}—, a sulfonyl group, —SO₄-, or a combination thereof is more preferable.

Regarding Alkylene Oxide Structure (D¹, D²)

From the viewpoint of adjusting a hydrophilic/hydrophobic ratio in the compound, it is preferable that the release agent has an alkylene oxide structure. It is preferable that the alkylene oxide structure is a structure consisting of only a linear alkylene group (preferably an ethylene group) and an oxygen atom.

Specific examples of the alkylene oxide structure include methylene oxide, ethylene oxide, propylene oxide, and butylene oxide.

The numbers y1 and y2 of times of repetition of the alkylene oxide structure each independently represent 0 or more, preferably 1 or more, more preferably 4 or more, and still more preferably 5 or more. In addition, the numbers y1 and y2 represent 30 or less, preferably 25 or less, and more preferably 20 or less. It is more preferable that y1 and y2 represent an integer of 5 to 20. In a case where y1 and y2 are excessively small, the proportion of hydrophobic groups in the release agent increases, and the wettability on a mold deteriorates, and filling properties may deteriorate. Conversely, in a case where y1 and y2 are excessively large, the proportion of hydrophobic groups decreases, and releasability may deteriorate.

Regarding Terminal Group (F′, F²)

A terminal group of the release agent is F¹ (polar functional group) or F² (a hydrogen atom, a linear aliphatic hydrocarbon group having 4 to 11 carbon atoms (preferably 4 to 9 carbon atoms), a branched aliphatic hydrocarbon group having 5 to 18 carbon atoms, or an aliphatic hydrocarbon group having 5 to 11 carbon atoms that has a cyclic structure having 5 or 6 carbon atoms, and a fluorine atom is not included).

Specific examples of the polar functional group include a hydroxyl group, an amino group, a sulfonyl group-containing group, a sulfino group, a sulfonimidoyl group-containing group, and a carboxyl group. In particular, from the viewpoint of practicality, a hydroxyl group, an amino group, a sulfonyl group-containing group (in particular, a sulfonyl group, a sulfo group, or a sulfonamide group), or a carboxyl group is preferable. It is preferable that the sulfonyl group-containing group is a sulfonyl group (—SO₂R), a sulfonamide group (R—SO₂—NH—), a sulfamoyl group (—SO₂NH₂), or a sulfo group (—SO₃H). It is preferable that the sulfonimidoyl group-containing group is —SO(NH)R. R represents an alkyl group (having preferably 1 to 24 carbon atoms, more preferably 1 to 12 carbon atoms, and still more preferably 1 to 6 carbon atoms), an alkenyl group (having preferably 2 to 24 carbon atoms, more preferably 2 to 12 carbon atoms, and still more preferably 2 to 6 carbon atoms), or an aryl group (having preferably 6 to 22 carbon atoms, more preferably 6 to 18 carbon atoms, and still more preferably 6 to 10 carbon atoms).

A preferable range of F² is the same as A¹.

In Formula (I), it is preferable that A¹ represents a linear aliphatic hydrocarbon group having 4 to 9 carbon atoms. In Formula (II), it is preferable that A² represents a linear aliphatic hydrocarbon group having 4 to 9 carbon atoms and F² represents a linear aliphatic hydrocarbon group having 4 to 9 carbon atoms.

In Formula (I), a polar functional group is present at a terminal such that the release agent is likely to be unevenly dispersed on a mold surface, and an effect of improving releasability can be expected.

Formula (I) is preferably the following Formula (I-1) or (I-2) and more preferably Formula (I-1).

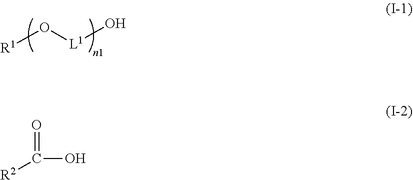

L¹ represents a methylene group, an ethylene group, a propylene group, or a butylene group.

R¹ represents the same group as A¹, and a preferable range thereof is also the same.

n1 represents the same number as y1, and a preferable range thereof is also the same.

R² represents the same group as A¹, and a preferable range thereof is also the same. However, the chain of the aliphatic hydrocarbon group may include one or less linking group (for example, O, S, or NH) having a heteroatom with respect to two carbon atoms.

Formula (II) is preferably any one of the following Formulae (II-1) to (II-3) and more preferably Formula (II-1).

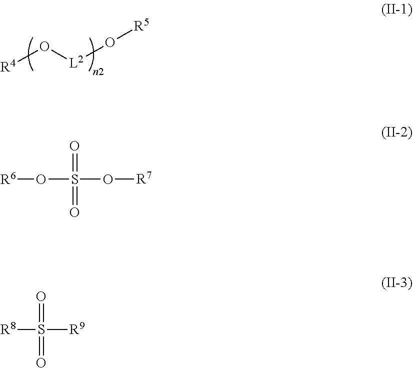

L² represents a methylene group, an ethylene group, a propylene group, or a butylene group.

R⁴ and R⁵ each independently represent the same group as A², and a preferable range thereof is also the same.

n2 represents the same number as y2, and a preferable range thereof is also the same.

R⁶ and R⁷ each independently represent the same group as A², and a preferable range thereof is also the same.

R⁸ and R⁹ each independently represent the same group as A², and a preferable range thereof is also the same.

The weight-average molecular weight of the release agent is preferably 300 or higher, more preferably 350 or higher, still more preferably 400 or higher, still more preferably 450 or higher, and still more preferably 500 or higher. The upper limit of the molecular weight is preferably 1,500 or lower and more preferably 1000 or lower, may be 950 or lower, and may be 920 or lower.

The mixing amount of the release agent in the curable composition for imprinting is preferably 0.5 mass % or higher, more preferably 1.0 mass % or higher, and still more preferably 2.0 mass % or higher with respect to non-volatile components. In addition, the mixing amount is preferably 7.0 mass % or lower, more preferably 5.0 mass % or lower, and still more preferably 4.0 mass % or lower with respect to non-volatile components. By adjusting the amount of the release agent to be the lower limit value or more, releasability can be effectively exhibited. By adjusting the amount of the release agent to be the upper limit value or less, filling properties are improved, and pattern surface roughening can be effectively suppressed.

The curable composition for imprinting may include one release agent or two or more release agents. In a case where the curable composition for imprinting according to the embodiment of the present invention includes two or more release agents, it is preferable that the total content of the two or more release agents is in the above-described range.

Specific examples of the release agent include Compounds C-1 to C-15 described below in Examples and the following compounds C-31 to C-37.

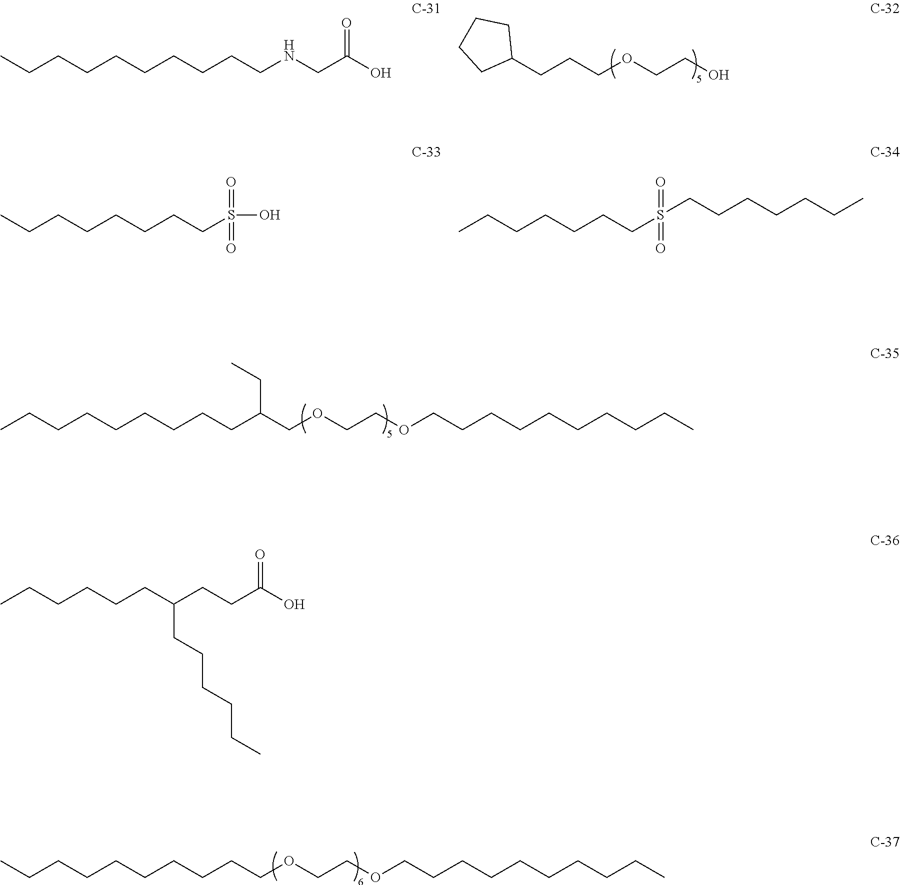

<<Photopolymerization Initiator>>

The curable composition for imprinting according to the embodiment of the present invention includes a photopolymerization initiator.

As the photopolymerization initiator used in the present invention, any compound that generates an active species for polymerization of the above-described polymerizable compounds by light irradiation can be used. As the photopolymerization initiator, a photoradical polymerization initiator or a photocationic polymerization initiator is preferable, and a photoradical polymerization initiator is more preferable.

As the photoradical polymerization initiator used in the present invention, for example, a commercially available initiator can be used. For example, compounds described in paragraph “0091” of JP2008-105414A can be preferably adopted. In particular, an acetophenone compound, an acylphosphine oxide compound, or an oxime ester compound is preferable from the viewpoints of curing sensitivity and absorption properties.

Specifically, for example, the following photopolymerization initiators can be used.

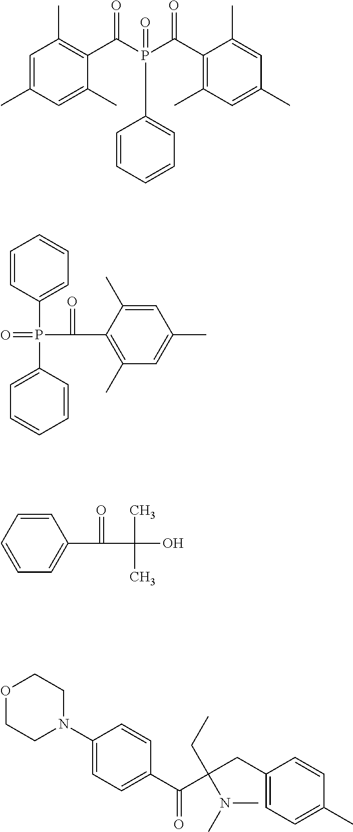

As the photopolymerization initiator, one kind may be used alone, but it is preferable that two or more kinds are used in combination. In a case where two or more kinds of photoradical polymerization initiators are used in combination, it is more preferable that two or more kinds of photoradical polymerization initiators are used in combination.

The content of the photopolymerization initiator used in the present invention is preferably 0.01 to 15 mass %, more preferably 0.1 to 10 mass %, still more preferably 0.5 to 7 mass %, and still more preferably 1 to 5 mass % with respect to the total content of the composition excluding the solvent. In a case where two or more photopolymerization initiators are used, the total content of the photopolymerization initiators is in the above-described range. In a case where the content of the photopolymerization initiator is 0.01 mass % or higher, sensitivity (fast curing properties) resolution ability, line edge roughness, and coating film hardness tends to be further improved, which is preferable. In addition, in a case where the content of the photopolymerization initiator is 15 mass % or lower, light-transmitting property, colorability, handleability, and the like tend to be further improved, which is preferable.

<Other Components>

In addition to the above-described components, the curable composition for imprinting used in the present invention may further include other components within a range not departing from the scope of the present invention. Examples of the other components include a surfactant, a sensitizer, an antioxidant, a polymerization inhibitor (for example, 4-hydroxy-2,2,6,6-tetramethylpiperidine-1-oxyl free radical), an ultraviolet absorber, and a solvent. As each of these compounds, only one kind may be included, and two or more kinds may be included. The details of the other components can be found in paragraphs “0061” to “0064” of JP2014-170949A, the content of which is incorporated herein by reference.

As described above, it is preferable that the curable composition for imprinting according to the embodiment of the present invention does not substantially include a solvent. “Substantially not including” represents that the content of the solvent is 3 mass % or lower, preferably 1 mass % or lower, and more preferably 0.5 mass % or lower with respect to the curable composition for imprinting.

This way, the curable composition for imprinting according to the embodiment of the present invention does not necessarily include a solvent. However, a solvent may be optionally added, for example, in order to finely adjust the viscosity of the composition. Examples of the kind of the solvent which can be preferably used in the curable composition according to the embodiment of the present invention include solvents which are generally used in a curable composition for imprinting or a photoresist. The solvent is not particularly limited as long as it can dissolve and uniformly disperse the compound used in the present invention and is not reactive with the components. Examples of the solvent which can be used in the present invention include solvents described in paragraph “0088” of JP2008-105414A, the content of which is incorporated herein by reference.

In addition, it is preferable that the curable composition for imprinting according to the embodiment of the present invention does not substantially include a component having a molecular weight of 2000 or higher. “Substantially not including” represents that the content of the component having a molecular weight of 2000 or higher is 3 mass % or lower, preferably 1 mass % or lower, and more preferably 0.5 mass % or lower with respect to non-volatile components of the curable composition for imprinting.

<Properties of Curable Composition for Imprinting>

The Ohnishi parameter of the curable composition for imprinting according to the embodiment of the present invention is preferably 5.0 or lower, more preferably 4.0 or lower, still more preferably 3.9 or lower, still more preferably 3.7 or lower, and still more preferably 3.6 or lower. By adjusting the Ohnishi parameter to be 5.0 or lower, etching resistance tends to be further improved.

The lower limit value of the Ohnishi parameter may be 3.0 or higher and 3.5 or higher.

It is preferable that the viscosity of the curable composition for imprinting at 23° C. is 20 mPa·s or lower and the solvent content is 3 mass % or lower with respect to the curable composition for imprinting. The viscosity is measured using a method described below in Examples.

In a composition including only the polymerizable compound among the components included in the curable composition for imprinting at a ratio at which the curable composition for imprinting includes the polymerizable compound, it is preferable that a surface tension at 23° C. is 33 mN/m or higher. The surface tension is measured using a method described below in Examples.

The curable composition for imprinting according to the embodiment of the present invention may be filtered before use. For filtering, for example, a polytetrafluoroethylene (PTFE) filter or a Nylon filter can be used. In addition, the pore size during filtering is preferably 0.003 μm to 5.0 μm. The details of filtering can be found in paragraph “0070” of JP2014-170949A, the content of which is incorporated herein by reference.

In addition, the present invention discloses a cured product which is obtained by curing the curable composition for imprinting according to the embodiment of the present invention. It is preferable that the cured product is provided on a silicon substrate.

A pattern forming method according to an embodiment of the present invention includes: applying the curable composition for imprinting according to the embodiment of the present invention to a substrate or a mold; and irradiating the curable composition for imprinting with light in a state where the curable composition for imprinting is interposed between the mold and the substrate.

In addition, after forming an underlayer film, an adhesive film, or a primer film (liquid film) is formed on a surface of a substrate, the curable composition for imprinting may be applied thereto.

A pattern that is formed using the pattern forming method according to the embodiment of the present invention is useful as an etching resist (mask for lithography). In a case where the pattern is used as an etching resist, first, a silicon substrate (for example, silicon wafer) on which a thin film such as SiO₂ is formed is used as a substrate, and, for example, a nano or micro-order fine pattern is formed on the substrate using the pattern forming method according to the embodiment of the present invention. In the present invention, the above-described configuration is advantageous from the viewpoint that, in particular, a nano-order fine pattern can be formed and a pattern having a size of 25 nm or less, in particular, 20 nm or less can also be formed. The lower limit value of a pattern size formed using the pattern forming method according to the embodiment of the present invention is not particularly limited and may be, for example, 10 nm or more. Here, the size of the pattern refers to the smallest dimension in the pattern that is formed using the pattern forming method according to the embodiment of the present invention. In the case of a line pattern, the pattern size refers to a line width of the pattern. In the case of a pillar/hole pattern, the pattern size refers to the diameter of the pattern.

Next, the substrate is etched by using etching gas, for example, hydrogen fluoride or the like in the case of wet etching or CF₄ or CHF₃/CF₄/Ar mixed gas in the case of dry etching. As a result, a desired pattern can be formed on the substrate. The pattern has excellent etching resistance to, in particular, dry etching. That is, the pattern that is formed using the manufacturing method according to the embodiment of the present invention is preferably used a mask for lithography.

The details of the pattern forming method can be found in paragraphs “0057” to “0071” of JP2015-185798A, the content of which is incorporated herein by reference.

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples.

<Preparation of Curable Compositions for Imprinting>

Various compounds shown in Tables 1 to 3 were mixed with each other, and 4-hydroxy-2,2,6,6-tetramethylpiperidine-1-oxyl free radical (manufactured by Tokyo Chemical Industry Co., Ltd.) was added as a polymerization inhibitor such that the content thereof 200 mass ppm (0.02 mass %) with respect to the content of all the polymerizable compounds. This mixture was filtered through a Nylon filter having a pore size of 0.02 μm, a PTFE filter having a pore size of 0.01 μm, and an UPE filter having a pore size of 0.001 μm to prepare a curable composition for imprinting.

<Measurement of Weight-Average Molecular Weight (Mw)>

The weight-average molecular weight of the release agent was calculated using LC-MS (high-speed liquid chromatograph/mass spectrometer). TSKgel ODS-80 Ts (manufactured by TOSOH Corporation) was used as a column for LC, and H₂O/MeOH (both of which are products dissolved in ammonium acetate) was used as an eluent. ESI-Posi was used as an MS ionization method. By grasping a molecular weight distribution from the MS spectrum, the weight-average molecular weight Mw was calculated. MeOH represents methanol.

TSKgel ODS-80 Ts (manufactured by TOSOH Corporation): diameter 2.0 mm (inner diameter) 150 mm

Eluent: A solution: H₂O (10 mM CH₃COONH₄), B solution: MeOH (10 mM CH₃COONH₄)

Gradient Condition: Bconc. 50% (0 min.)→100% (20 min.)→100% (40 min.)

Flow rate: 0.2 mL/min.

Injection volume: 2 μL

Column temperature: 40° C.

MS ionization method: ESI positive

Detection: quantitative analysis was performed using peaks of two components detected from samples in a 1 TIC mode and a 2 SIM mode

1 m/z=616, 664

Derived from [H(C₃H₆O)n+OH+NH₄]+(n=10, 11)

<Measurement of Viscosity>

The viscosity was measured using an E-type rotary viscometer RE85L (manufactured by Toki Sangyo Co., Ltd.) with a standard cone rotor (1° 34′×R24) after adjusting the temperature of a sample cup to 23° C. The unit was mPa·s. The other details regarding the measurement were based on JIS K 8803:2011. Two samples were prepared for each level and the measurement was performed three times. Six arithmetic mean values in total were adopted as evaluation values.

<Measurement of Surface Tension>

The surface tension of each of the compositions or the compounds was measured at 23° C. using a surface tensiometer SURFACE TENS-IOMETER CBVP-A3 (manufactured by Kyowa Interface Science Co., Ltd.) and a glass plate. The unit was mN/m. Two samples were prepared for each level and the measurement was performed three times. Six arithmetic mean values in total were adopted as evaluation values.

<Releasability>

As a quartz mold, a quartz mold having a line/space [L:S=1:1] with a line width of 20 nm and a depth of 55 nm was used. Using an ink jet printer (DMP-2831, manufactured by Fujifilm Dimatix Inc.) as an ink jet device, the above-described curable composition for imprinting was applied to a silicon wafer (silicon substrate) using an ink jet method, and was interposed between the mold and the silicon wafer in a helium atmosphere. Regarding a jetting pattern by ink jet, the arrangement was a rhombus lattice shape, the interval was diagonal line: 140 μm/80 and the jetting amount was 1 μL. The curable composition for imprinting was exposed under a condition of 100 mJ/cm² from the quartz mold side using a high pressure mercury lamp, and then the quartz mold was released. As a result, a pattern was obtained.

In the pattern obtained as described above, a force (releasing force F; unit: N) required for releasing the quartz mold was measured. In detail, the releasing force was measured using a method described in Comparative Example of Paragraphs “0102” to “0107 of JP2011-206977A.

A: F≤15 N

B: 15N<F≤18 N

C: 18N<F≤20 N

D: F>20 N

<Ink Jet (IJ) Jettability (Ink Jet Suitability)>

IJ jettability was evaluated using an ink jet printer DMP-2831 (manufactured by Fujifilm Dimatix Inc.). Jetting conditions such as a jetting waveform or a jetting voltage were optimized while observing a jetting state of the composition with an adjusted temperature of 23° C. with a CCD camera (CCD image sensor). Five jetting ports where jetting was most stable were selected, and the composition was jetted to a silicon wafer at an interval of 100 μm (square arrangement) (jetting area: 5 mm×5 mm, 2500 dots). An investigation was performed by replacing an ink jet nozzle to change the jetting amount to 1 pL and 6 pL.

In a case where the investigation was continuously performed five times, the observation of the jetting state using the CCD camera and deviation of the jetted liquid droplets from the square arrangement were evaluated.

A: jetting was stable in all the nozzles, and deviation of liquid droplets was not observed over the entire surface of the jetting region.

B: flight bending and jetting port contamination were observed in some nozzles, and deviation of liquid droplets was observed in a part of the region.

C: flight bending and jetting port contamination were observed in 50% or higher of the nozzles, and deviation of liquid droplet and failure of liquid droplet application were observed over the entire surface of the jetting region.

<Pattern Formability>

The pattern prepared for the evaluation of the releasing force was observed, and the evaluation was performed as follows.

A: excellent pattern transfer was observed over the entire surface.

B: pattern surface roughening or pattern missing was observed.

C: both pattern surface roughening and pattern missing were observed.

<Filling Properties>

As a quartz mold, a quartz mold (arrangement: square arrangement, pitch: 4 μm) was used, the quartz mold having a recessed structure in which each of openings had a circular shape with a radius of 1 μm and the depth was 2 μm. Using an ink jet printer (DMP-2831, manufactured by Fujifilm Dimatix Inc.) as an ink jet device, the above-described curable composition for imprinting was applied to a silicon wafer using an ink jet method, and was interposed between the mold and the silicon wafer in a helium atmosphere.

A state where the curable composition for imprinting was filled into the concave portion of the quartz mold was observed using a CCD camera, and the time required for the completion of the filling was measured.

A: shorter than 3 seconds

B: 3 seconds or longer and shorter than 5 seconds

C: 5 seconds or longer and shorter than 10 seconds

D: 10 seconds or longer

TABLE 1

| | | Example | Example | Example | Example | Example |
|---|---|---|---|---|---|---|
| | | 1 | 2 | 3 | 4 | 5 |
| Polymerizable | A-1 | 60 | 60 | 60 | 58 | 60 |
| Compound | A-2 | 20 | | | | 15 |
| | A-3 | | 20 | 20 | 20 | |
| | A-4 | | | | | |
| | A-5 | 15 | 15 | 15 | | |
| | A-6 | | | | 15 | |
| | A-7 | | | | | 20 |
| | A-8 | | | | | |
| | A-9 | | | | | |
| | A-10 | | | | | |
| | A-11 | | | | | |
| Polymerization | B-1 | 2 | 2 | 2 | 2 | |
| Initiator | B-2 | | | | | 2 |
| | B-3 | | | | 2 | |
| Release | C-1 | 3 | | | | |
| Agent | C-2 | | 3 | | | |
| | C-3 | | | 3 | | |
| | C-4 | | | | 3 | |
| | C-5 | | | | | 3 |
| | C-6 | | | | | |
| | C-7 | | | | | |
| | C-8 | | | | | |
| | C-9 | | | | | |
| | C-10 | | | | | |
| | C-11 | | | | | |
| | C-12 | | | | | |
| | C-13 | | | | | |
| | C-14 | | | | | |
| | C-15 | | | | | |
| | C-16 | | | | | |
| | C-17 | | | | | |
| | C-18 | | | | | |
| | C-19 | | | | | |
| | C-20 | | | | | |
| | C-21 | | | | | |
| | C-22 | | | | | |
| Total (Part(s) by Mass) | | 100 | 100 | 100 | 100 | 100 |
| Surface Tension (mN/m) of | | 35 | 35 | 34 | 35 | 34 |
| Polymerizable Compound at 23° C. | | | | | | |
| Viscosity (mPa · s) of Composition | | 6 | 6 | 6 | 7 | 7 |
| for Imprinting at 23° C. | | | | | | |
| Surface Tension (mN/m) of Composition | | 31 | 33 | 34 | 33 | 32 |
| for Imprinting at 23° C. | | | | | | |
| Evaluation of Releasing Force | | A | A | B | A | A |
| Evaluation of Ink Jet Suitability | | A | B | A | A | A |
| Evaluation of Pattern Formability | | A | A | A | A | A |
| Evaluation of Filling Properties | | A | B | A | A | A |
| | | Example | Example | Example | Example | Example |
| | | 6 | 7 | 8 | 9 | 10 |
| Polymerizable | A-1 | 60 | 60 | 62.6 | 55.5 | 50 |
| Compound | A-2 | | 20 | 20 | | |
| | A-3 | 20 | | | 20 | 35 |
| | A-4 | | | | | |
| | A-5 | | | | | |
| | A-6 | 15 | 15 | 15 | | 10 |
| | A-7 | | | | 15 | |
| | A-8 | | | | | |
| | A-9 | | | | | |
| | A-10 | | | | | |
| | A-11 | | | | | |
| Polymerization | B-1 | 2 | 1 | 1 | | 1 |
| Initiator | B-2 | | | | 1 | |
| | B-3 | | 1 | 1 | 1 | 1 |
| Release | C-1 | | | 0.4 | 7.5 | 3 |
| Agent | C-2 | | | | | |
| | C-3 | | | | | |
| | C-4 | | | | | |
| | C-5 | | | | | |
| | C-6 | 3 | | | | |
| | C-7 | | 3 | | | |
| | C-8 | | | | | |
| | C-9 | | | | | |
| | C-10 | | | | | |
| | C-11 | | | | | |
| | C-12 | | | | | |
| | C-13 | | | | | |
| | C-14 | | | | | |
| | C-15 | | | | | |
| | C-16 | | | | | |
| | C-17 | | | | | |
| | C-18 | | | | | |
| | C-19 | | | | | |
| | C-20 | | | | | |
| | C-21 | | | | | |
| | C-22 | | | | | |

| | | | | | |
|---|---|---|---|---|---|
| Total (Part(s) by Mass) | 100 | 100 | 100 | 100 | 100 |
| Surface Tension (mN/m) of | 35 | 35 | 35 | 35 | 32 |
| Polymerizable Compound at 23° C. | | | | | |
| Viscosity (mPa · s) of Composition | 7 | 7 | 7 | 8 | 6 |
| for Imprinting at 23° C. | | | | | |
| Surface Tension (mN/m) of Composition | 33 | 32 | 35 | 31 | 31 |
| for Imprinting at 23° C. | | | | | |
| Evaluation of Releasing Force | A | A | B | A | A |
| Evaluation of Ink Jet Suitability | B | B | A | B | A |
| Evaluation of Pattern Formability | A | A | A | B | A |
| Evaluation of Filling Properties | A | B | A | B | B |

Mixing Amount: by mass (hereinafter, the same shall be applied)

TABLE 2

| | | Example | Example | Example | Example | Example | Example | Example | Example | Example |
|---|---|---|---|---|---|---|---|---|---|---|
| | | 11 | 12 | 13 | 14 | 15 | 16 | 17 | 18 | 19 |
| Polymerizable | A-1 | 60 | 60 | 90 | 60 | 55 | 60 | 60 | 50 | 50 |
| Compound | A-2 | | | | 20 | 5 | 20 | | 20 | 20 |
| | A-3 | | 15 | | | 20 | | 20 | | |
| | A-4 | 20 | | | | | | | | |
| | A-5 | | | | | | | | | |
| | A-6 | | | 5 | 15 | 15 | 15 | | | |
| | A-7 | 15 | | | | | | | 25 | |
| | A-8 | | 20 | | | | | 15 | | 25 |
| | A-9 | | | | | | | | | |
| | A-10 | | | | | | | | | |
| | A-11 | | | | | | | | | |
| Polymerization | B-1 | 2 | 2 | 2 | 1 | 2 | 2 | 1 | 2 | 2 |
| Initiator | B-2 | | | | | | | | | |
| | B-3 | | | | 1 | | | 1 | | |
| Release | C-1 | 3 | | | | | | | | |
| Agent | C-2 | | | | | | | | | |
| | C-3 | | | | | | | | | |
| | C-4 | | | | | | | | | |
| | C-5 | | | | | | | | | |
| | C-6 | | | | | | | | | |
| | C-7 | | | | | | | | | |
| | C-8 | | 3 | | | | | | | |
| | C-9 | | | 3 | | | | | | |
| | C-10 | | | | 3 | | | | | |
| | C-11 | | | | | 3 | | | | |
| | C-12 | | | | | | 3 | | | |
| | C-13 | | | | | | | 3 | | |
| | C-14 | | | | | | | | 3 | |
| | C-15 | | | | | | | | | 3 |
| | C-16 | | | | | | | | | |
| | C-17 | | | | | | | | | |
| | C-18 | | | | | | | | | |
| | C-19 | | | | | | | | | |
| | C-20 | | | | | | | | | |
| | C-21 | | | | | | | | | |
| | C-22 | | | | | | | | | |

| | | | | | | | | | |
|---|---|---|---|---|---|---|---|---|---|
| Total (Part(s) by Mass) | 100 | 100 | 100 | 100 | 100 | 100 | 100 | 100 | 100 |
| Surface Tension (mN/m) of | 36 | 34 | 40 | 35 | 36 | 35 | 35 | 35 | 35 |
| Polymerizable Compound at 23° C. | | | | | | | | | |
| Viscosity (mPa · s) of Composition | 25 | 8 | 12 | 7 | 18 | 7 | 8 | 7 | 8 |
| for Imprinting at 23° C. | | | | | | | | | |
| Surface Tension (mN/m) of Composition | 34 | 27 | 39 | 33 | 33 | 32 | 34 | 32 | 34 |
| for Imprinting at 23° C. | | | | | | | | | |
| Evaluation of Releasing Force | A | A | A | A | A | A | A | A | A |
| Evaluation of Ink Jet Suitability | B | B | B | A | A | A | A | A | A |
| Evaluation of Pattern Formability | A | A | A | A | A | A | A | A | A |
| Evaluation of Filling Properties | B | A | A | A | A | A | A | B | B |

TABLE 3

| | | Comparative | Comparative | Comparative | Comparative | Comparative |
|---|---|---|---|---|---|---|
| | | Example 1 | Example 2 | Example 3 | Example 4 | Example 5 |
| Polymerizable | A-1 | 60 | 60 | 60 | | 60 |
| Compound | A-2 | 20 | | 20 | 50 | |
| | A-3 | | 20 | | | 20 |
| | A-4 | | | | | |
| | A-5 | | | 15 | 35 | |
| | A-6 | | | | 10 | |
| | A-7 | | | | | |
| | A-8 | | | | | |
| | A-9 | | | | | |
| | A-10 | | | | | |
| | A-11 | 15 | 15 | | | 15 |
| Polymerization | B-1 | 2 | 2 | 1 | 1 | |
| Initiator | B-2 | | | | | 2 |
| | B-3 | | | 1 | 1 | |
| Release | C-1 | | | | | |
| Agent | C-2 | | | | | |
| | C-3 | | | | | |
| | C-4 | | | | | |
| | C-5 | | | | | |
| | C-6 | | | | | |
| | C-7 | | | | | |
| | C-8 | | | | | |
| | C-9 | | | | | |
| | C-10 | | | | | |
| | C-11 | | | | | |
| | C-12 | | | | | |
| | C-13 | | | | | |
| | C-14 | | | | | |
| | C-15 | | | | | |
| | C-16 | 3 | | | | |
| | C-17 | | 3 | | | |
| | C-18 | | | 3 | | |
| | C-19 | | | | 3 | |
| | C-20 | | | | | 3 |
| | C-21 | | | | | |
| | C-22 | | | | | |
| Total (Part(s) by Mass) | | 100 | 100 | 100 | 100 | 100 |
| Surface Tension (mN/m) of | | 35 | 35 | 36 | 32 | 35 |
| Polymerizable Compound at 23° C. | | | | | | |
| Viscosity (mPa · s) of Composition | | 7 | 7 | 7 | 7 | 7 |
| for Imprinting at 23° C. | | | | | | |
| Surface Tension (mN/m) of Composition | | 31 | 31 | 30 | 31 | 34 |
| for Imprinting at 23° C. | | | | | | |
| Evaluation of Releasing Force | | C | A | B | A | A |
| Evaluation of Ink Jet Suitability | | A | A | B | B | B |
| Evaluation of Pattern Formability | | A | A | B | B | A |
| Evaluation of Filling Properties | | A | C | D | C | D |
| | | Comparative | Comparative | Comparative | Comparative | Comparative |
| | | Example 6 | Example 7 | Example 8 | Example 9 | Example 10 |
| Polymerizable | A-1 | | 60 | 60 | 60 | 60 |
| Compound | A-2 | 47 | | | 20 | |
| | A-3 | | 20 | 20 | 15 | 20 |
| | A-4 | | | | | |
| | A-5 | 38 | | | | |
| | A-6 | 10 | | | | |
| | A-7 | | | | | |
| | A-8 | | | | | |
| | A-9 | | | 15 | | |
| | A-10 | | | | | |
| | A-11 | | 15 | | | 15 |
| Polymerization | B-1 | 1 | 2 | 2 | 2 | 2 |
| Initiator | B-2 | | | | | |
| | B-3 | 1 | | | | |
| Release | C-1 | | | 3 | | |
| Agent | C-2 | | | | | |
| | C-3 | | | | | |
| | C-4 | | | | 3 | |
| | C-5 | | | | | 3 |
| | C-6 | | | | | |
| | C-7 | | | | | |
| | C-8 | | | | | |
| | C-9 | | | | | |
| | C-10 | | | | | |
| | C-11 | | | | | |
| | C-12 | | | | | |
| | C-13 | | | | | |
| | C-14 | | | | | |
| | C-15 | | | | | |
| | C-16 | | | | | |
| | C-17 | | | | | |
| | C-18 | | | | | |
| | C-19 | | | | | |
| | C-20 | | | | | |
| | C-21 | 3 | | | | |
| | C-22 | | 3 | | | |

| | | | | | |
|---|---|---|---|---|---|
| Total (Part(s) by Mass) | 100 | 100 | 100 | 100 | 100 |
| Surface Tension (mN/m) of | 32 | 35 | 35 | 35 | 35 |
| Polymerizable Compound at 23° C. | | | | | |
| Viscosity (mPa · s) of Composition | 6 | 7 | 7 | 9 | 8 |
| for Imprinting at 23° C. | | | | | |
| Surface Tension (mN/m) of Composition | 22 | 33 | 33 | 33 | 33 |
| for Imprinting at 23° C. | | | | | |
| Evaluation of Releasing Force | A | D | D | D | D |
| Evaluation of Ink Jet Suitability | C | A | A | A | A |
| Evaluation of Pattern Formability | A | A | A | A | A |
| Evaluation of Filling Properties | D | B | B | B | B |

Polymerizable Compound

TABLE 4

| No | Chemical Formula |
|---|---|
| A-1 | 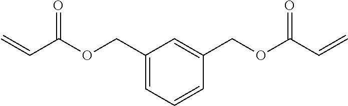 [SMILES: C=CC(=O)OCc1cccc(COC(=O)C=C)c1] |
| A-2 | 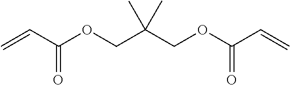 |
| A-3 | 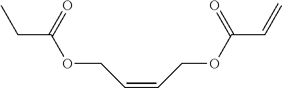 |
| A-4 | 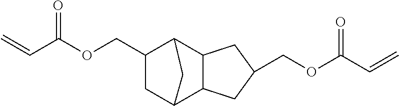 [SMILES: C=CC(=O)OCC1CC2C3CC(COC(=O)C=C)C(C3)C2C1] |
| A-5 | 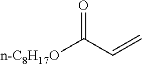 |
| A-6 | 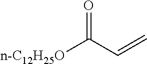 |
| A-7 | 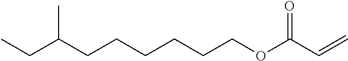 |
| A-8 | 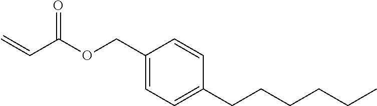 [SMILES: C=CC(=O)OCc1ccc(CCCCCC)cc1] |
| A-9 | 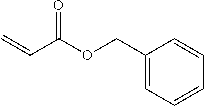 |
| A-10 | 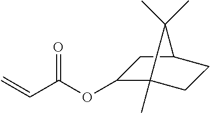 |
| A-11 | 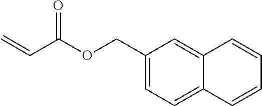 [SMILES: C=CC(=O)OCc1ccc2ccccc2c1] |

Polymerization Initiator

TABLE 5

| No | Chemical Formula |
|---|---|
| B-1 | 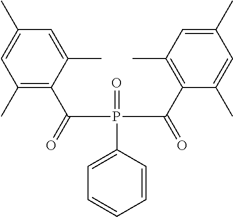 [SMILES: Cc1cc(C)c(C(=O)P(=O)(C(=O)c2c(C)cc(C)cc2C)c2ccccc2)c(C)c1] |
| B-2 | 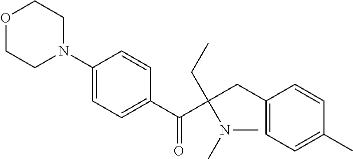 [SMILES: CCC(Cc1ccc(C)cc1)(C(=O)c1ccc(N2CCOCC2)cc1)N(C)C] |
| B-3 | 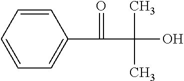 |

Release Agent

TABLE 6

| No | Chemical Formula | Mw |
|---|---|---|
| C-1 | 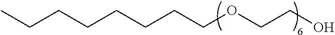 | 394 |
| C-2 | 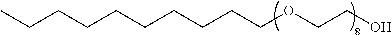 | 510 |
| C-3 | 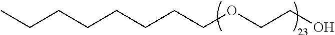 | 1142 |
| C-4 | 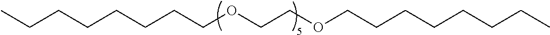 | 462 |
| C-5 | 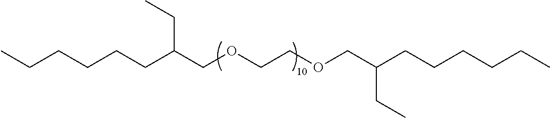 | 739 |
| C-6 | 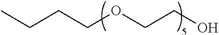 | 294 |
| C-7 | 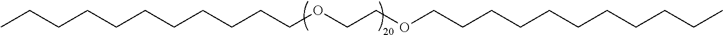 | 1206 |
| C-8 | 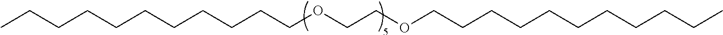 | 546 |

Mw: weight-average molecular weight (hereinafter, the same shall be applied)

TABLE 7

| No | Chemical Formula | Mw |
|---|---|---|
| C-9 | 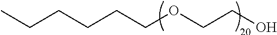 | 983 |
| C-10 | 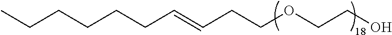 | 948 |
| C-11 | 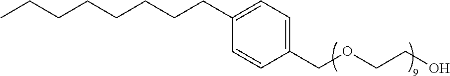 | 616 |
| C-12 | 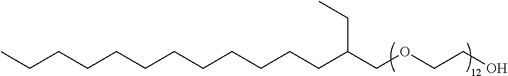 | 770 |
| C-13 | 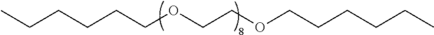 | 538 |
| C-14 | 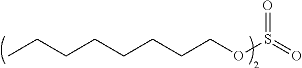 | 307 |
| C-15 | 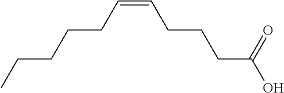 | 184 |

TABLE 8

| No | Chemical Formula | Mw |
|---|---|---|
| C-16 | 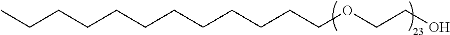 | 1198 |
| C-17 | 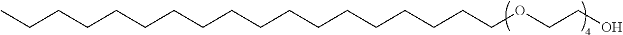 | 446 |
| C-18 | 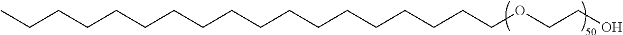 | 2473 |
| C-19 | 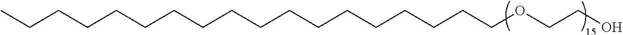 | 930 |
| C-20 | 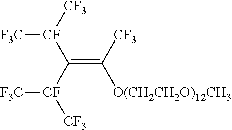 | 990 |
| C-21 | 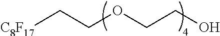 | 640 |
| C-22 | 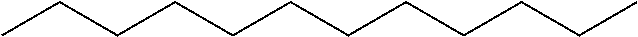 | 170 |

As can be seen from the above results, it was found that, in the curable compositions for imprinting including the monofunctional polymerizable compound having any one of the structures (1) to (3) specified in the present invention and the release agent satisfying Formula (I) or Formula (II), excellent releasability and excellent filling properties were able to achieved at the same time (Examples 1 to 19). In addition, high performance for ink jet suitability or pattern formability was also obtained.

On the other hand, in the curable compositions for imprinting (Comparative Examples 1 to 10) including a monofunctional polymerizable compound not having any one of the structures (1) to (3) specified in the present invention and a release agent not satisfying Formula (I) or Formula (II), the performance of either releasability or filling properties was poor, and both releasability and filling properties were not able to be achieved at the same time.

What is claimed is:

1. A curable composition for imprinting comprising:
a monofunctional polymerizable compound;
a photopolymerization initiator; and
a release agent,
wherein the monofunctional polymerizable compound has any one of the following structures (1) to (3):
(1) a linear alkyl group having 8 or more carbon atoms;
(2) a branched alkyl group having 10 or more carbon atoms; and
(3) an alicyclic ring, an aromatic ring, or an aromatic heterocycle that is substituted with a linear alkyl group having 1 or more carbon atoms or a branched alkyl group having 3 or more carbon atoms, and
the release agent is represented by the following Formula (I) or Formula (II),
A¹-(B¹)ₓ₁-(D¹)_{y1}-(E¹)_{z1}-F¹ Formula (I),
in Formula (I), A¹ represents a linear aliphatic hydrocarbon group having 4 to 11 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, A¹ does not have a fluorine atom, B¹ represents a divalent linking group in which a binding site to A¹ is not an aliphatic hydrocarbon group, x1 represents 0 or 1, D¹ represents an alkylene oxide structure, E¹ represents a divalent linking group in which a binding site to F¹ is not an aliphatic hydrocarbon group, F¹ represents a polar functional group, y1 represents an integer of 0 to 30, and z1 represents 0 or 1, and
A²-(B²)ₓ₂-(D²)_{y2}-(E²)_{z2}-F²: Formula (II),
in Formula (II), A² represents a linear aliphatic hydrocarbon group having 4 to 11 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, A² does not have a fluorine atom, B² represents a divalent linking group in which a binding site to A² is not an aliphatic hydrocarbon group, x2 represents 0 or 1, D² represents an alkylene oxide structure, E² represents a divalent linking group in which a binding site to F² is not an aliphatic hydrocarbon group, F² represents a hydrogen atom, a linear aliphatic hydrocarbon group having 4 to 11 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, F² does not have a fluorine atom, y2 represents an integer of 0 to 30, z2 represents 0 or 1, and in a case where y2 represents 0, B² or E² represents a polar functional group.

2. The curable composition for imprinting according to claim 1, comprising:
a release agent in which A¹ represents a linear aliphatic hydrocarbon group having 4 to 9 carbon atoms.

3. The curable composition for imprinting according to claim 1, comprising:
a release agent in which A² represents a linear aliphatic hydrocarbon group having 4 to 9 carbon atoms and F² represents a linear aliphatic hydrocarbon group having 4 to 9 carbon atoms.

4. The curable composition for imprinting according to claim 1,
wherein the polar functional group is selected from the group consisting of a hydroxyl group, an amino group, a sulfonyl group-containing group, a sulfino group, a sulfonimidoyl group-containing group, and a carboxyl group.

5. The curable composition for imprinting according to claim 1,
wherein y1 and y2 each independently represent an integer of 5 to 20.

6. The curable composition for imprinting according to claim 1,
wherein x1 and x2 represent 0.

7. The curable composition for imprinting according to claim 1,
wherein in Formula (I), A¹ represents a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, and y1 represents an integer of 5 to 20, or
in Formula (II), A² represents a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, F² represents a hydrogen atom, a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, and y2 represents an integer of 5 to 20.

8. The curable composition for imprinting according to claim 1,
wherein a weight-average molecular weight of the release agent is 300 to 1000.

9. The curable composition for imprinting according to claim 1,
wherein a content of the release agent is 0.5 mass % to 7.0 mass % with respect to non-volatile components.

10. The curable composition for imprinting according to claim 1,
wherein the polymerizable compound included in the curable composition for imprinting exhibits a surface tension of 33 mN/m or higher at 23° C.

11. The curable composition for imprinting according to claim 1,
wherein a viscosity of the polymerizable compound included in the curable composition for imprinting is 20 mPa·s or lower, and
a solvent content in the composition is 3 mass % or lower with respect to the curable composition for imprinting.

12. The curable composition for imprinting according to claim 1,
wherein a surface tension of the curable composition for imprinting at 23° C. is 28 mN/m to 38 mN/m.

13. A release agent represented by the following Formula (I) or Formula (II),
A¹-(B¹)ₓ₁-(D¹)_{y1}-(E¹)_{z1}-F¹ Formula (I),
in Formula (I), A¹ represents a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, A¹ does not have a fluorine atom, B¹ represents a divalent linking group in which a binding site to A¹ is not an aliphatic hydrocarbon group, x1 represents 0 or 1, B¹ represents an alkylene oxide structure, E¹ represents a divalent linking group in which a binding site to F¹ is not an aliphatic hydrocarbon group, F¹ represents a polar functional group, y1 represents an integer of 5 to 20, and z1 represents 0 or 1, and
A²-(B²)ₓ₂-(D²)_{y2}-(E²)_{z2}-F² Formula (II),
in Formula (II), A² represents a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, A² does not have a fluorine atom, B² represents a divalent linking group in which a binding site to A² is not an aliphatic hydrocarbon group, x2 represents 0 or 1, D² represents an alkylene oxide structure, E² represents a divalent linking group in which a binding site to F² is not an aliphatic hydrocarbon group, F² represents a hydrogen atom, a linear aliphatic hydrocarbon group having 4 to 9 carbon atoms, a branched aliphatic hydrocarbon group having 5 to 18 carbon atoms, or an aliphatic hydrocarbon group having 5 to 11 carbon atoms that has a cyclic structure having 5 or 6 carbon atoms, F² does not have a fluorine atom, y2 represents an integer of 5 to 20, z2 represents 0 or 1, and in a case where y2 represents 0, B² or E² represents a polar functional group.

14. The release agent according to claim 13, which is used for a curable composition for imprinting.

15. A cured product which is obtained by curing the curable composition for imprinting according to any one of claim 1.

16. The cured product according to claim 15, which is provided on a silicon substrate.

17. A pattern forming method comprising:
applying the curable composition for imprinting according to claim 1 to a substrate or a mold; and
irradiating the curable composition for imprinting with light in a state where the curable composition for imprinting is interposed between the mold and the substrate.

18. The pattern forming method according to claim 17,
wherein a pattern to be formed has a shape of any one of a line, a ball, or a pillar having a size of 20 nm or less.

19. A lithography method comprising:
performing etching by using a pattern which is obtained using the pattern forming method according to claim 17 as a mask.
